(19) United States
(12) Patent Application Publication
(10) Pub. No.: US 2025/0210071 A1
(43) Pub. Date: Jun. 26, 2025

(54) SUPERBLOCK-BASED PROGRAMMING-TEMPERATURE AWARENESS IN STORAGE DEVICES

(71) Applicant: InnoGrit Technologies Co., Ltd., Shanghai (CN)

(72) Inventors: Chenrong Xiong, San Jose, CA (US); Youngjoon Choi, Shanghai (CN); William Fu, San Jose, CA (US); Charlie Dong, San Jose, CA (US); Jie Chen, Shanghai (CN)

(21) Appl. No.: 18/396,611

(22) Filed: Dec. 26, 2023

(51) Int. Cl. G11C 7/04; G11C 7/10; G11C 7/14

(52) U.S. Cl. CPC G11C 7/04; G11C 7/1069; G11C 7/14

(57) ABSTRACT

A controller, a method, a system, and a non-transitory machine-readable medium are provided for reducing Fail Bits Count (FBC) caused by the cross-temperature effect. In one embodiment, a controller may comprise a processor configured to obtain a record from a storage. The record comprises a representation of a programing temperature of a superblock of non-volatile memories. The non-volatile memories are on a plurality of dies. The superblock comprises blocks of the non-volatile memories and the blocks are not on the same die. The processor is further configured to determine a reference voltage based on the representation of the programing temperature and to read a page of the superblock using the reference voltage.

### BACKGROUND

The development of NAND memory has witnessed significant progress, leading to continuous enhancements in storage density and performance. This trend has positioned NAND memory as a crucial element in modern storage technology, offering dependable and efficient data storage solutions.

NAND memory operates by utilizing the accumulation and release of electric charges. Through voltage control, charges are stored in the floating gate of a NAND memory cell, representing the logical states of individual bits. During the process of data readout, a voltage is applied to the memory cell to measure the variations in the gate voltage, enabling the determination of data states. When writing data, specific voltage levels are applied to either accumulate or release charges within the memory cell, thereby modifying the data states. This mechanism allows for the reliable storage and retrieval of data in the NAND memory.

The threshold voltage Vth is used to define different states of a NAND memory cell. In the case of a single-level cell (SLC), a single threshold voltage Vth is used to define two states, “1” and “0”. In the case of a multi-level cell (MLC), three threshold voltages, Vth0, Vth1, and Vth2, are used to define four states, “11”, “10”, “01”, and “00”. In the case of a triple-level cell (TLC), seven threshold voltages are used to define eight states, “111”, “110”, “101”, “100”, “011”, “010”, “001”, and “000”. In the case of a quad-level cell (QLC), fifteen threshold voltages are used to define sixteen states, “1111”, “1110”, “1101”, “1100”, “1011”, “1010”, “1001”, “1000”, “0111”, “0110”, “0101”, “0100”, “0011”, “0010”, “0001”, and “0000”.

NAND memory cells are composed of different materials that exhibit varying levels of resistance to changes in temperature. As the temperature rises or falls, the threshold voltage Vth of NAND memory cells may change as well.

It is known that cell conductance, sensing trip level, and the reference voltages used for verifying the programmed data and during read operations are influenced by temperature. This phenomenon is commonly known as the cross-temperature effect. FIG. 1 may be helpful for better understanding this effect.

FIG. 1 schematically illustrates the disparity in threshold voltage distributions and the respective reference voltages between high and low temperatures, taking TLC (Triple Level Cell) as an example. The threshold voltage distribution and the reference voltages V_{R1}, V_{R2}, V_{R3}, V_{R4}, V_{R5}, V_{R6}, and V_{R7} at a higher temperature are shown in solid lines, while the threshold voltage distribution and the reference voltages V′_{R1}, V′_{R2}, V′_{R3}, V′_{R4}, V′_{R5}, V′_{R6}, and V′_{R7} at a lower temperature are shown in dashed lines.

It can be seen from FIG. 1 that the lines representing threshold voltage distributions and the respective reference voltages at the lower temperature condition is shifted to the right (higher in voltage) in comparison to the lines representing those at the higher temperature condition.

Due to the cross-temperature effect, if a NAND page is read at a temperature different from the temperature at which it was programmed, a high Fail Bits Count (FBC) may occur.

To reduce the FBC caused by the cross-temperature effect, the reference voltages should be carefully adjusted.

### SUMMARY

The present disclosure provides a controller of and a method of operating a non-volatile storage system that incorporate superblock-based programing temperature awareness.

In an embodiment, the controller may have a processor configured to obtain a record from a storage. The record includes a representation of a programing temperature of a superblock of non-volatile memories of the non-volatile storage system. The non-volatile memories are on a plurality of dies. The superblock includes blocks of the non-volatile memories and the blocks are not on the same die. The processor is further configured to determine a reference voltage based on the representation of the programing temperature and to read a page of the superblock using the reference voltage.

In an embodiment, the method may include obtaining a record from a storage. The record includes a representation of a programing temperature of a superblock of non-volatile memories. The non-volatile memories are on a plurality of dies. The superblock has blocks of the non-volatile memories and the blocks are not on the same die. The method may further includes determining a reference voltage based on the representation of the programing temperature, and reading a page of the superblock using the reference voltage.

In an embodiment, a system such as a solid-state drive (SSD), a flash drive, a mother board, a processor, a computer, a server, a gaming device, or a mobile device may include the controller described in this disclosure.

In an embodiment, a non-transitory machine-readable medium may have information stored in it. The information, when read by a hardware processor system, causes the hardware processor system to perform any method in this disclosure.

### BRIEF DESCRIPTION OF FIGURES

FIG. 1 schematically illustrates the disparity in threshold voltage distributions and the respective reference voltages between high and low temperatures.

FIG. 2A schematically show a non-volatile storage system.

FIG. 2B schematically show a non-volatile storage system.

FIG. 3 is a flowchart of a process of programing data into a non-volatile storage system.

FIG. 4 is a flowchart of a process of reading data from a non-volatile storage system.

FIG. 5 is a flowchart of a process of error correction.

FIG. 6 schematically shows an example of the programing temperature information for a superblock divided into multiple groups of blocks.

FIG. 7 is a flowchart of a page reading process in accordance with Embodiment I of the present disclosure.

FIG. 8 is a flowchart of a page reading process in accordance with Embodiment II of the present disclosure.

FIG. 9 schematically shows an example of the programing temperature information that can be used in Embodiment III.

FIG. 10 schematically shows another example of the programing temperature information that can be used in Embodiment III.

FIG. 11 is a flowchart of a page reading process in accordance with Embodiment III of the present disclosure.

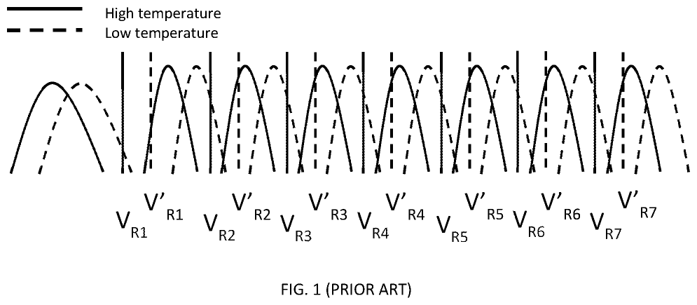

### DETAILED DESCRIPTION

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

A non-volatile storage system, a controller of the non-volatile storage system and a method of operating the non-volatile storage system as disclosed herein may reduce the FBC caused by the cross-temperature effect.

Characterization of the non-volatile memories (e.g., NAND memories) of the non-volatile storage system may be used to prepare different reference voltage settings for different program-read temperature combinations. For example, assuming the operational temperature range for a memory cell of the non-volatile memories is 0-80° C., the operational temperature range can be divided into four temperature segments, 0-20° C., 20-40° C., 40-60° C., and 60-80° C. These temperature segments are indexed by 0, 1, 2, and 3, respectively. A cross-temperature reference voltage table with 16 entries can be provided by the characterization, as shown in the table below. Each entry is represented as Entry[i][j], where i and j are the indexes of segments of the read temperature and the programing temperature, respectively.

TABLE 1

| | Programming Temp. | | | |
|---|---|---|---|---|
| | 0-20° C. | 20-40° C. | 40-60° C. | 60-80° C. |
| Read Temp. | (0) | (1) | (2) | (3) |
| 0-20° C. (0) | Entry[0][0] | Entry[0][1] | Entry[0][2] | Entry[0][3] |
| 20-40° C. (1) | Entry[1][0] | Entry[1][1] | Entry[1][2] | Entry[1][3] |
| 40-60° C. (2) | Entry[2][0] | Entry[2][1] | Entry[2][2] | Entry[2][3] |
| 60-80° C. (3) | Entry[3][0] | Entry[3][1] | Entry[3][2] | Entry[3][3] |

The cross-temperature reference voltage table can be a look-up table, with rows corresponding to the respective read temperature segments and columns corresponding to the respective programing temperature segments.

When a page is to be read from the non-volatile memories of a non-volatile storage system, if the programing temperature of the page and the current read temperature are available, the entry associated with the programing temperature and the read temperature can be used for the read operation.

For example, if the programing temperature of a page is known to be 30° C., the programing temperature segment index is 1. If the current read temperature is 50° C. (corresponding to the read temperature segment index of 2), Entry[2][1] should be used to read the page, which may help to reduce the FBC.

Although the current read temperature is easy to obtain, e.g., by using a temperature sensor 110 when the page is ready to read, the programing temperature of a page is usually difficult to obtain unless it is stored somewhere in the non-volatile storage system. If the programing temperature is not stored, all the reference voltage settings associated with a read temperature are tried one by one. In the above example, the read operation first attempts Entry [2][0]. If the read operation fails (i.e., any error in the data read cannot be corrected), it proceeds to try Entry [2][1], Entry [2][2], and Entry [2][3] in sequential, until a successful read operation is achieved. In this situation, the average read number to get the page data correctly is around (1+2+3+4)/4=2.5 for the cross-temperature test by assuming the programing temperature is uniformly distributed between 0° C. and 80° C.

If the programing temperature is stored in the non-volatile memories, extra read operations may be needed to retrieve the PTI. This could increase the read latency further and make the performance of the non-volatile storage system worse.

If the programing temperature of every wordline is stored, there would be too much memory overhead. For example, if the non-volatile storage system has a capacity of 1 TB with QLC cells, the memory overhead is (1 TB/16 KB/4)×7=14 MB.

Blocks in the non-volatile storage system with the same block ID across multiple planes and multiple dies are grouped together into a single superblock to enhance throughput and performance. A superblock can be divided into several groups (“block groups”).

The non-volatile storage system may maintain some information (SPB INFO, i.e., SuPerBlock Information) for a superblock. The SPB INFO may include but is not limited to the number of P/E cycles, indexes of bad blocks, open block status, and the time stamp of first programming for the superblock. The SPB INFO could be stored in SRAM of the controller, DRAM in the non-volatile storage system or the non-volatile memories. The SPB INFO may include a representation of the programing temperature (“programing temperature information” or “PTI”) of the superblock.

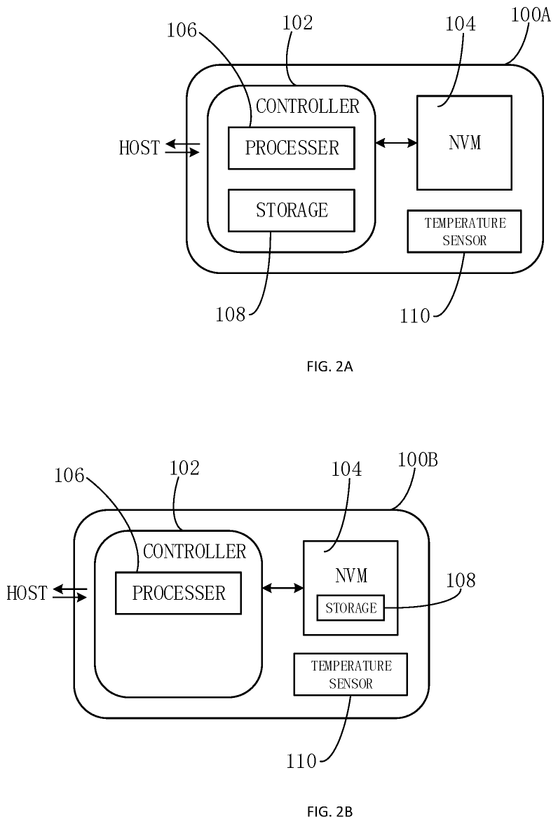

FIG. 2A and FIG. 2B schematically show non-volatile storage systems 100A and 100B, respectively.

The non-volatile storage system 100A or 100B may include a controller 102 and non-volatile memories (NVM) 104. The non-volatile storage system 100A or 100B may provide data storage and/or access to stored data to a host when it is coupled to the host. The NVM 104 may be NAND memories.

As mentioned before, the reference voltage for reading data stored in the NVM 104 may be affected by the real-time on-die temperature. The on-die temperature may refer to the temperature of the NVM 104. A temperature sensor 110 may be included in the non-volatile storage system 100A or 100B to measure the on-die temperature.

The controller 102 may have a processor 106. The processor 106 may be a computer processor, such as, but not limited to, a microprocessor or a microcontroller.

The processor 106 is configured to obtain a record from a storage 108 of the non-volatile storage system 100A or 100B. The record includes a representation of a programing temperature of a superblock of the NVM 104.

The term “programing temperature of a superblock” should mean a temperature during programing the superblock. The word “during” should include the beginning and the end.

FIG. 2A shows an embodiment in which the storage 108 is in the controller 102, while FIG. 2B shows an embodiment in which the storage 108 is part of the NVM 104. The storage 108 may be at any location in the non-volatile storage system 100A or 100B.

The NVM 104 may be on a plurality of dies. The superblock includes blocks of the NVM 104 and the blocks are not on the same die. For example, the superblock may include blocks with the same block ID across multiple planes and multiple dies.

The processor 106 may be further configured to determine a reference voltage based on the representation of the programing temperature and to read a page of the superblock using the reference voltage.

As mentioned above, the superblock may be divided into a plurality of block groups. In some embodiments, the record may further include an index of a block group among the plurality of block groups. The processor 106 may be configured to determine the reference voltage further based on the index of the block group.

In some embodiments, the processor 106 may be configured to determine the reference voltage further based on a representation of a temperature of the NVM 104 at a time of determining the reference voltage. This temperature can be referred to as “read temperature” for simplicity.

The expression “a temperature of the non-volatile memories at a time of determining the reference voltage” or “read temperature” does not mean the temperature measured at the exact moment when determining the reference voltage. It could be a temperature measured a while before the determination or an average temperature during a time period before the determination. Normally, the read temperature does not change rapidly. Therefore, a temperature measured a while before the exact moment of determination or an average temperature during a time period before the exact moment of determination may be used as a temperature at a time of determining the reference voltage.

In some embodiments, the processor 106 can be configured to determine the reference voltage further based on an index of the superblock.

In some embodiments, the processor 106 may be configured to read the page of the superblock using the reference voltage with an offset. In some cases, the offset might be a positive offset, the processor 106 may be configured to read using a voltage of (Vref+Vdelta), where Vref is the reference voltage determined above, and +Vdelta is the positive offset. In some cases, the offset might be a negative offset, the processor 106 may be configured to read using a voltage of (Vref−Vdelta), where Vref is the reference voltage determined above, and −Vdelta is the negative offset.

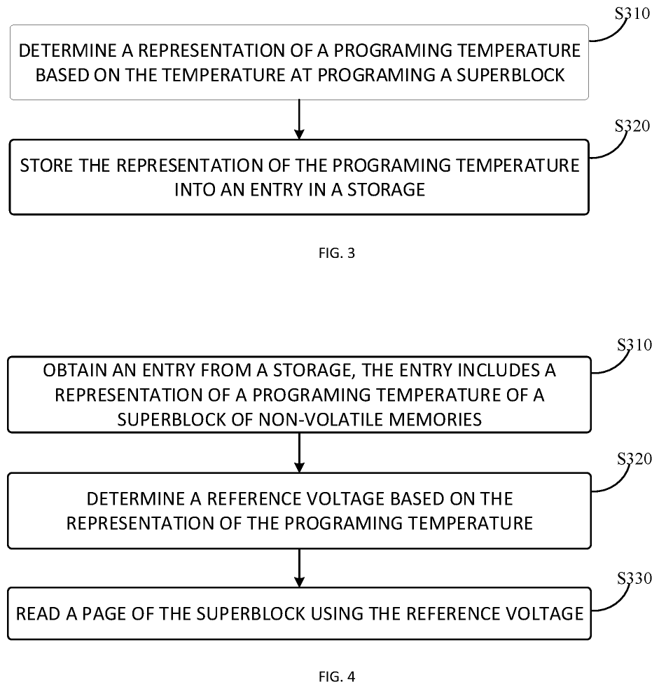

FIG. 3 is a flowchart of a process of programing data into the non-volatile storage system. The process shown in FIG. 3 can be performed by the processor 106 as shown in FIG. 2A or FIG. 2B. In other words, the processor 106 can be configured to perform the process shown in FIG. 3.

In step S310 of the process of FIG. 3, a representation of a programing temperature is determined based on the temperature at which the superblock is programmed. In step S320, the representation of the programing temperature is stored into a record in the storage 108.

FIG. 4 is a flowchart of a process of reading data from the non-volatile storage system. The process shown in FIG. 4 can be performed by the processor 106 as shown in FIG. 2A or FIG. 2B. In other words, the processor 106 can be configured to perform the process shown in FIG. 4.

In step S410 of the process of FIG. 4, a record is obtained from the storage 108. As mentioned above, the record has a representation of a programing temperature of the superblock. In step S420, a reference voltage is determined based on the representation of the programing temperature. The reference voltage may be determined further based on the index of the block group. In some embodiments, the reference voltage may be determined further based on the read temperature. In some embodiments, the reference voltage may be determined further based on an index of the superblock. In step S430, a page of the superblock may be read using the reference voltage. As mentioned above, in some embodiments, the page of the superblock may be read using the reference voltage with an offset.

Below is an example of a data reading process using a look-up table (e.g., Table 1), which can be performed by the processor 106.

When a page is ready for reading, the block group index of the page may be used as an index to obtain the PTI associated with the block group.

Based on the PTI and the current read temperature (e.g., measured by the temperature sensor 110), an entry is selected from the look-up table and the reference voltage in the entry is used to read the page.

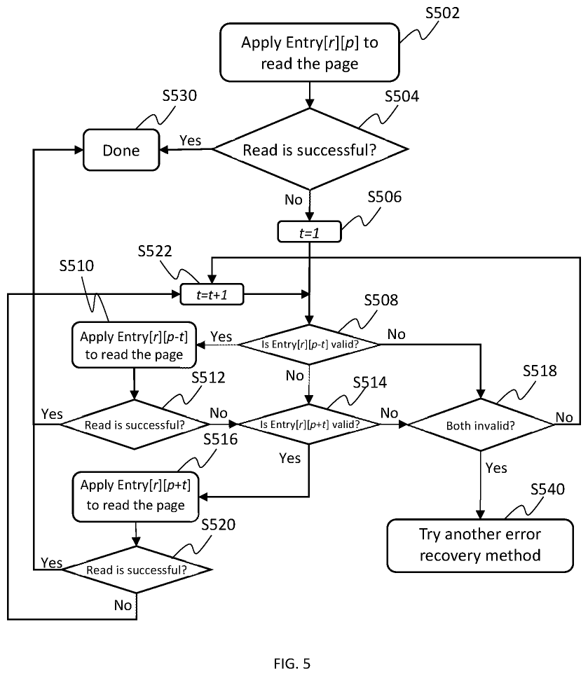

If reading using the reference voltage in the selected entry is unsuccessful or unsatisfactory, entries in the same row (corresponding to the same read temperature) of the look-up table may be tried one by one (e.g., in the order of increasing absolute value of the difference between the programing temperature segment indexes of the selected entry and those of the entries in the same row). This process will be further described below with reference to FIG. 5.

FIG. 5 is a flowchart of a process of error recovery when applying the entry obtained by using the PTI and the current read temperature.

As shown in FIG. 5, Entry[r][p] is the selected entry based on the PTI with temperature segment index p and the current read temperature with temperature segment index r. In other words, the read operation can be started with the reference V in Entry[r][p].

In step S502, Entry[r][p] is applied to read the page (i.e., the page is read using the reference voltage in Entry[r][p]). In step S504, it is determined whether the read operation is successful.

If the read operation is successful, the read operation is done in step S530.

If the read operation is unsuccessful (i.e., the page cannot be read correctly by using the reference voltage in Entry[r][p]), another read attempt will be performed by using the reference voltage in Entry[r][p−1] or the reference voltage in Entry[r][p+1]. If these two immediate neighbors fail again. Entry[r][p−2] and Entry[r][p+2] will be attempted until all entries in the same row (i.e., Entry[r][ . . . ]) are tried. If all of them are unsuccessful, another error recovery method such as soft read could be used.

In step S506, t is set 1.

In step S508, it is determined whether Entry[r][p−t] is valid. An entry is valid if it can be found in the look-up table. If it is valid, the process turns to step S510. If it is not valid, the process turns to step S514.

In step S510, Entry[r][p−t] is applied to read the page. In step S512, it is determined whether the read operation is successful. If the read operation is successful, the read operation is done in step S530. If the read operation is unsuccessful, the process turns to step S514.

In step S514, it is determined whether Entry[r][p+t] is valid. If it is valid, the process turns to step S516.

In step S516, Entry[r][p+t] is applied to read the page. In step S520, it is determined whether the read operation is successful. If the read operation is successful, the read operation is done in step S530. If the read operation is unsuccessful, the process turns in step S522.

In step S522, the parameter t is incremented by 1, i.e., t=t+1, and then the process turns to step S508 for another iteration.

If Entry[r][p+t] is invalid as determined in step S514, the process turns to step S518. In step S518, if it is determined whether both Entry[r][p−t] and Entry[r][p+t] are invalid, the process turns to step S540 to try another error recovery method. In step S518, if it is determined whether both Entry[r][p−t] and Entry[r][p+t] are not invalid, the process turns to step S522 to start another iterations.

Hereinafter, embodiments with various ways of representation of the programing temperature will be described in more detail.

As described above, the representation of the programing temperature is stored into a record in the storage 108 while programing data into the NVM 104, and is retrieved from the record obtained from the storage 108 when reading data from the NVM 104.

In some embodiments, the representation of the programing temperature is the programing temperature itself. For example, exact programming temperature values as measured, such as “25° C.”, “28° C.”, “27° C.” and so on, can be used as the representation of the programing temperature.

In some embodiments, the representation of the programing temperature is a temperature segment index representing a range the programing temperature is in. For example, indexes “0”, “1”, “2” and “3”, respectively representing temperature segments 0-20° C., 20-40° C., 40-60° C., and 60-80° C., can be used as representation of the programing temperature.

In some embodiments, the representation of the programing temperature comprises a first representation of a first programing temperature of a first block group among the plurality of block groups and a second representation of a second programing temperature of a second block group among the plurality of block groups.

The expression “first programing temperature of a first block group” means a temperature during programing the first block group, and the expression “second programing temperature of a second block group” means a temperature during programing the second block group. The term “first block group” and the term “second block group” do not indicate any particular order but any block group among the plurality of block groups.

In some further embodiments, the first programing temperature is the temperature measured at the beginning or the end of programming the first block group.

Using the representation of the programing temperature, the reference voltage can be determined based on the first representation of the first programing temperature and the second representation of the second programing temperature. The processor 106 may be configured to determine the reference voltage based on the first representation of the first programing temperature and the second representation of the second programing temperature.

In some embodiments, the reference voltage may be determined by interpolation or extrapolation, using the first representation of the first programing temperature and the second representation of the second programing temperature. The processor 106 may be configured to determine the reference voltage by interpolation or extrapolation, using the first representation of the first programing temperature and the second representation of the second programing temperature.

Interpolation or extrapolation may be used in at least two situations.

In one situation, if some block groups have no programing temperature stored in the storage 108, the programing temperature of the block groups may be estimated by interpolation or extrapolation. For example, the first block group has a block group index of 0, and the first programing temperature is 25° C.; the second block group has a block group index of 4, and the second programing temperature is 45° C. The programing temperatures of block groups with group indexes of 1, 2 and 3 are not stored in the storage 108. Then, the programing temperatures of block groups with group indexes of 1, 2 and 3 may be determined by interpolation (e.g., as 30° C., 35° C., 40° C., respectively); and the programing temperatures of block groups with group indexes of 5 and 6 can be determined by extrapolation (e.g., as 50° C., and 55° C., respectively).

In the other situation, the programing temperature of a block group may be used as the programing temperature of the page to be read, while only one programing temperature is stored for the block group, for example, at the beginning or the end of programing the block group. The programing temperature of a block in the block group (current block group) can be estimated by interpolation using the programing temperatures of the current block group and the next block group, or by extrapolation using the programing temperatures of the previous block group and the current block group. An example for such interpolation is described in Embodiment I below.

In some embodiments, if the programing temperature segment indexes of the first block group and block groups between the first block group and the second block group are the same, the PTI of the block groups between the first and second block groups are not stored. When reading data from the NVM 104, the programing temperature segment indexes of block groups between the first and second block groups can be determined as the first representation of the first programing temperature, and the reference voltage for these block groups can be determined based on the first representation of the first programing temperature.

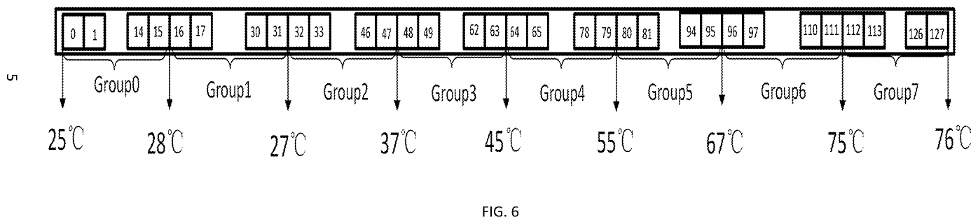

FIG. 6 schematically shows an example of the PTI for a superblock divided into multiple block groups. Embodiments I and II below will be described based on this example.

In the example show in FIG. 6, a superblock has 128 blocks with block indexes of 0 to 127 respectively. The 128 blocks are divided into 8 block groups with block group indexes of 0 to 7 respectively. Each block group has 16 blocks.

When the superblock is programmed, the PTI detected by the temperature sensor 110 at the start point of each block group is stored into a record, as the PTI in the SPB INFO. The temperature at the end of the superblock programming can be stored as well. As shown in FIG. 6, the programing temperatures at the start points of blocks with indexes of 0, 16, 32, 48, 64, 80, 96 and 112 (start points of block groups with indexes of 0 to 7), and at the end point of block with index of 127 are 25° C., 28° C., 27° C., 37° C., 45° C., 55° C., 67° C., 75° C. and 76° C. respectively.

Assuming the operational temperature range for a NAND is 0-80° C., and is divided into four temperature segments, 0-20° C., 20-40° C., 40-60° C., and 60-80° C., with temperature segment indexes of 0, 1, 2, and 3 respectively. The temperature segment indexes of the programing temperatures at the start point of block groups with indexes of 0 to 7 shown in FIG. 6 are 1, 1, 1, 1, 2, 2, 3 and 3 respectively.

The PTI as shown in FIG. 6 can be stored in different ways, as described below.

### Embodiment I

In embodiment I, the PTI could be the accurate temperature value provided by the temperature sensor 110. In other words, the representation of the programing temperature is the programing temperature.

The temperature information in the beginning of program operation, i.e. the programing temperature for each block group is detected by the temperature sensor 110 and stored into a record in the storage 108, as a part of the SPB INFO.

When an interpolation method is used to estimate the programing temperature of some block group, the temperature value at the end of the programming of a superblock is also written into the record, as a part of the SPB INFO.

In the example shown in FIG. 6, the respective detected values 25° C., 28° C., 27° C., 37° C., 45° C., 55° C., 67° C., 75° C. and 76° C. will be stored into the record as the PTI.

The table below shows the PTI stored in the record for the superblock in the storage 108, as a part of the SPB INFO, in the Embodiment I. The respective temperature values are stored.

| Block group index | Programing temperature information (PTI) (° C.) |
|---|---|
| 0 | 25 |
| 1 | 28 |
| 2 | 27 |
| 3 | 37 |
| 4 | 45 |
| 5 | 55 |
| 6 | 67 |
| 7 | 75 |
| END | 76 |

By storing the actual temperature values in Embodiment I, the SPB INFO memory overhead for the PTI is 8×7 bits+7 bits=63 bits.

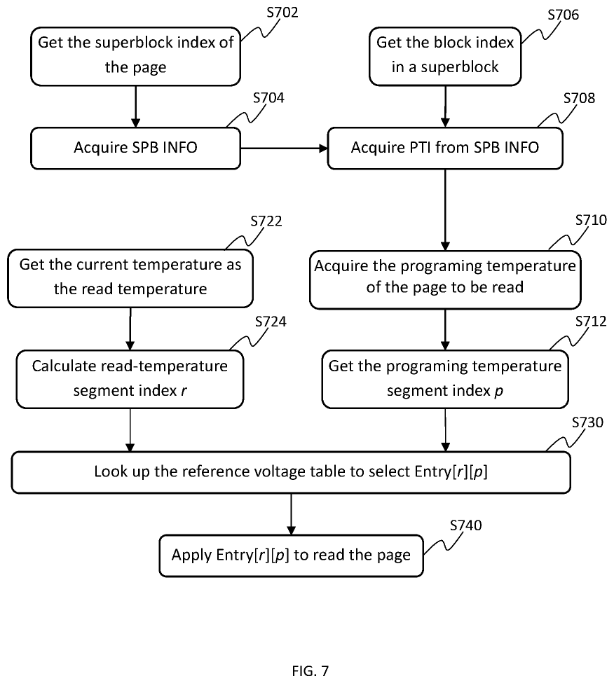

FIG. 7 is a flowchart of a page reading process.

When a page is about to be read, in step S702, the superblock index of the superblock containing the page can be acquired, for example, based on the L2P (Logical address to Physics address) table.

In step S704, the SPB INFO associated with the superblock can be acquired, from the storage 108 for example. As described above, the SPB INFO comprises a representation of the programing temperature of the superblock, or PTI.

In step S706, the block index of the page in a superblock is obtained, and further, the block group index can be calculated, which may provide the index for the PTI.

In step S708, the PTI of the block group containing the page to be read can be acquired from the SPB INFO.

In step S710, the programing temperature of the page to be read can be acquired from the PTI.

In Embodiment I, the PTI is the temperature value. There might be two ways to get the programing temperature.

The first one, which can be referred to as the “direct-map method”, is to take the programing temperature associated with the block group containing the page to be read as the programing temperature of the page to be read.

The second one, which can be referred to as the “interpolation method”, is to take the estimated programing temperature of the block containing the page to be read as the programing temperature of the page to be read.

Since only one programing temperature is stored for a block group, for example, at the beginning or the end of programing the block group, the programing temperature of a block contained in the block group (current block group) can be estimated by interpolation (or extrapolation) using the programing temperature values of the current block group and the next block group.

The interpolation may be done as follows.

Assuming a block group has N blocks. The page to be read is in the k-th block of the g-th block group, and the programing temperatures of the g-th and the (g+1)-th block groups stored in the SPB INFO are T(g) and T(g+1) respectively. Here both k and g are non-negative integers.

The estimated programing temperature of the page to be read may be:

$$T ( g ) + k \times ( T ( g + 1 ) - T ( g ) ) / N .$$

In step S712, the programing temperature of the page to be read as acquired in step S710 can be converted to the temperature segment index p.

On the other hand, when the page is about to be read, in step S722, the current read temperature can be acquired by using the temperature sensor 110.

And then, in step S724, the read temperature segment index r can be calculated from the current read temperature.

With the read temperature segment index r and the programing temperature segment index p are available, in step S730, Entry[r][p] can be selected by looking up a reference voltage table (e.g., Table 1).

In step S740, the reference voltage in Entry[r][p] can be applied to read the page.

As described above with reference to FIG. 5, an error recovery method may be performed. Assume Entry[r][p] is selected. If the page cannot be read correctly by using the reference voltage in Entry[r][p], another read retry will be performed by using the reference voltage in Entry[r][p−1] or Entry[r][p+1]. If these two immediate neighbors fail again, the reference voltages in Entry[r][p−2] and Entry[r][p+2] will be tried until all Entry[r][ . . . ] are tried. If the reference voltage in any of them can be used to read the page correctly, another error recovery method such as soft read could be used.

Below, an example of reference voltage selection of Embodiment I is described.

Assuming the page to read belongs to block 63 and the current temperature is 10° C. The read temperature segment index r is 0, i.e., r=0.

The programing temperature of block groups are stored as the PTI, or the representation of the programing temperature. Each block group includes 16 blocks.

According to the first method, or direct-map method, the programing temperature value of block group is taken as the programing temperature value of the page to be read.

The page to be read belongs to block 63, which is the last block in Group 3.

The programing temperature value of block group 3 is 37, as in the example shown in FIG. 6. And thus, the programing temperature segment index p for the page to be read is 1, i.e., p=1.

Therefore, according to the first method, the reference voltage in Entry[0][1] will be used to read the page.

According to the error recovery process described before with reference to FIG. 5, if the reference voltage in Entry[0][1] is unsuccessful, i.e., the read operation fails, then Entry[0][0], Entry[0][2], and Entry[0][3] will be tried one by one.

On the other hand, according to the second method, or interpolation method, the estimated programing temperature of block 63 will be taken as the programing temperature value of the page to be read.

The page to be read belongs to block 63, which is the last block in Group 3. The next group is Group 4.

The programing temperature values acquired from the SPB INFO for Group 3 and Group 4 are 37 and 45, respectively, as in the example shown in FIG. 6. The estimated programing temperature for the page is:

$$7 + 15 \times ( 45 - 37 ) ) / 16 = 44.5 .$$

Accordingly, the corresponding programing temperature segment index p is 2, i.e., p=2.

Therefore, according to the second method, the reference voltage in Entry[0][2] will be used to read the page.

According to the error recovery process described before with reference to FIG. 5, if reading the page using the reference voltage in Entry[0][2] fails, then Entry[0][1], Entry[0][3], and Entry[0][0] will be tried one by one.

### Embodiment II

In Embodiment II, the PTI could be a temperature segment index corresponding to the temperature provided by the temperature sensor 110. In other words, the representation of the programing temperature is a temperature segment index representing a range the programing temperature is in.

The temperature information in the beginning of program operation for each group is detected by the temperature sensor 110 and stored into a record, as a part of the SPB INFO.

In the example shown in FIG. 6, the respective temperature segment indexes 1, 1, 1, 1, 2, 2, 3 and 3 will be stored into the record as the PTI.

The table below shows the PTI stored in the record for the superblock in the storage 108, as a part of the SPB INFO, in the Embodiment II. The respective temperature values are stored.

TABLE 2

| Block group index | Programing temperature information (PTI) |
|---|---|
| 0 | 1 |
| 1 | 1 |
| 2 | 1 |
| 3 | 1 |
| 4 | 2 |
| 5 | 2 |
| 6 | 3 |
| 7 | 3 |

By storing the temperature segment indexes in Embodiment II, the SPB INFO memory overhead for PTI is 8×2 bits=16 bits.

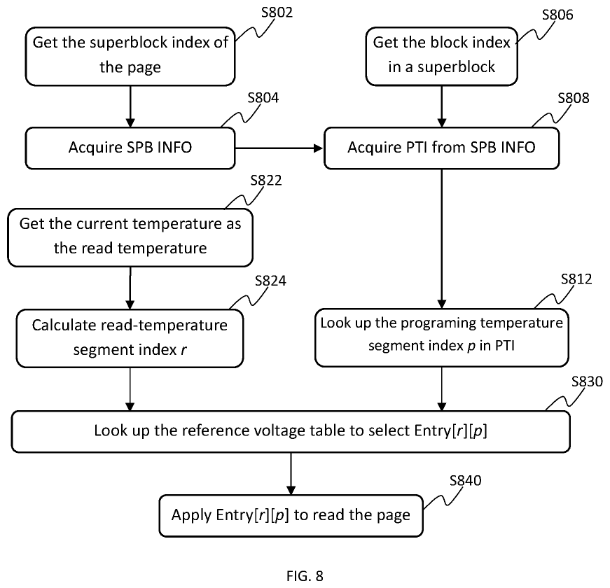

FIG. 8 is a flowchart of a page reading process in accordance with Embodiment II of the present disclosure.

In embodiment II, the PTI is the index of temperature segment. The PTI can be used directly to look up the reference voltage setting.

When a page is about to be read, in step S802, the superblock index of the superblock containing the page can be acquired, for example, based on the L2P (Logical address to Physics address) table.

In step S804, the SPB INFO associated with the superblock can be acquired, from the storage 108 for example. As described above, the SPB INFO comprises a representation of the programing temperature of the superblock, or PTI.

In step S806, the block index of the page in a superblock is obtained. The block group index can be calculated, which may provide the index for the PTI.

In step S808, the PTI of the block group containing the page to be read can be acquired from SPB INFO.

In step S812, the programing temperature segment index p can be obtained.

On the other hand, when the page is about to be read, in step S822, the current read temperature can be acquired by using the temperature sensor 110.

In step S824, the read temperature segment index r can be calculated accordingly.

With the read temperature segment index r and the programing temperature segment index p available, in step S830, Entry[r][p] can be selected by looking up the reference voltage table.

In step S840, the reference voltage in Entry[r][p] can be applied to read the page.

As described above with reference to FIG. 5, an error recovery process may be performed. Assuming Entry[r][p] is selected, if the page cannot be read correctly by using the reference voltage in Entry[r][p], another read retry will be performed by using the reference voltage in Entry[r][p−1] or Entry[r][p+1]. If the reference voltages of the immediate neighbors fail again. The reference voltages in Entry[r][p−2] and Entry[r][p+2] will be tried until all Entry[r][ . . . ] are tried. If all of them are unsuccessful, another error recovery method such as soft read could be used.

Below, an example of reference voltage selection of Embodiment II is described.

Assuming the page to read belongs to block 63 and the current temperature is 10° C. The temperature segment index for read r is 0, i.e., r=0.

The temperature segment index is stored as the PTI, or the representation of the programing temperature. And each block group includes 16 blocks.

The page to be read belongs to block 63, which is the last block in Group 3.

The programing temperature segment index of Group 3 obtained from the SPB INFO is 1. Thus, the programing temperature segment index p for the page to be read is 1, i.e., p=1.

Therefore, Entry[_{0][1}] will be used to read the page.

According to the error recovery process described before with reference to FIG. 5, if the reference voltage in Entry[0][1] is unsuccessful, i.e., the read operation fails, then the reference voltages in Entry[0][0], Entry[0][2], and Entry[0][3] will be tried one by one.

### Embodiment III

In embodiment III, the representation of the programing temperature comprises a programing temperature segment index of a block group and the index of the block group. In other words, the PTI could be a pair of values comprising both a block group index and a programing temperature segment index. If the programing temperature segment indexes are the same for multiple consecutive block groups, only the programming temperature information of the first one among the multiple consecutive block groups is stored in the record. For the PTI of the subsequent block groups among the multiple consecutive block groups of which the programming temperature segment indexes do not change, no PTI is stored in the record. And the PTI of a block group, after the multiple consecutive block groups, of which the programming temperature segment indexes changes, will be stored in the record.

Specifically, the index of the programing temperature segment (or programing temperature segment index) at the beginning of programming for every block group of the superblock is monitored.

The index of the programing temperature segment at the beginning of programming for the first block group of the superblock is stored in the record.

If the index of the programing temperature segment at the beginning of programming for a block group is different from the previously stored index of the programing temperature segment, both the index of the current block group and its corresponding programing temperature segment index are stored in the record.

On the other hand, if the index of the programing temperature segment at the beginning of programming for a block group is the same as that of the previously stored index, it is not necessary to store the PTI for this block group.

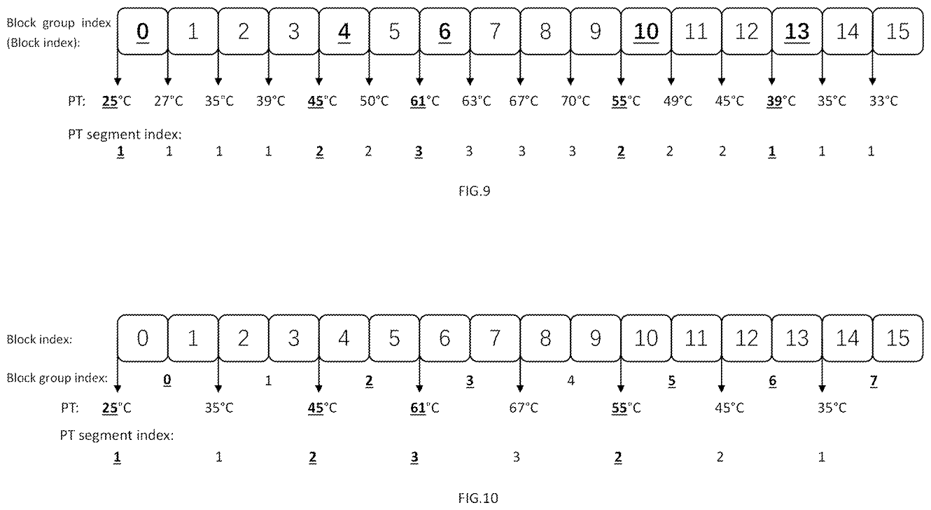

FIG. 9 schematically shows an example of the PTI that can be used in Embodiment III.

As shown in FIG. 9, a superblock has 16 blocks and 16 block groups. Each block group has only one block.

The indexes of the programing temperature segments are defined as follows: 0: 0-20° C., 1: 20-40° C., 2: 40-60° C., 3: 60-80° C.

The programing temperatures at the start points of the 16 block groups (or blocks) with indexes of 0 to 15 are 25° C., 27° C., 35° C., 39° C., 45° C., 50° C., 61° C., 63° C., 67° C., 70° C., 55° C., 49° C., 45° C., 39° C., 35° C. and 33° C., respectively. The programing temperature segment indexes of the 16 block groups (or blocks) with indexes of 0 to 15 are 1, 1, 1, 1, 2, 2, 3, 3, 3, 3, 2, 2, 2, 1, 1, 1, respectively.

The PTI stored in the record will be (0,1), (4,2), (6,3), (10,2), (13,1).

There are totally 5 entries for the PTI. For each PTI entry, the first data refers to the block group index, and the second data refers to the programing temperature segment index for the block group. The total memory size is 5× (4 bits+2 bits)=30 bits.

FIG. 10 schematically shows another example of the PTI that can be used in Embodiment III.

As shown in FIG. 10, a superblock has 16 blocks and eight block groups. Each block group has two blocks.

The Index of programing temperature segment are defined as follows: 0: 0-20° C., 1:20-40° C., 2:40-60° C., 3:60-80° C.

The programing temperatures at the start points of the 8 block groups with indexes of 0 to 7 are 25° C., 35° C., 45° C., 61° C., 67° C., 55° C., 45° C. and 35° C., respectively. The programing temperature segment indexes of the 8 block groups with indexes of 0 to 7 are 1, 1, 2, 3, 3, 2, 2, 1, respectively.

The PTI stored in the record will be (0,1), (2,2), (3,3), (5,2), (7,1).

There are totally 5 entries for the PTI. For each PTI entry, the first data refers to the block group index, and the second data refers to the programing temperature segment index for the block group. The total memory size is 5×(3+2)=25 bits.

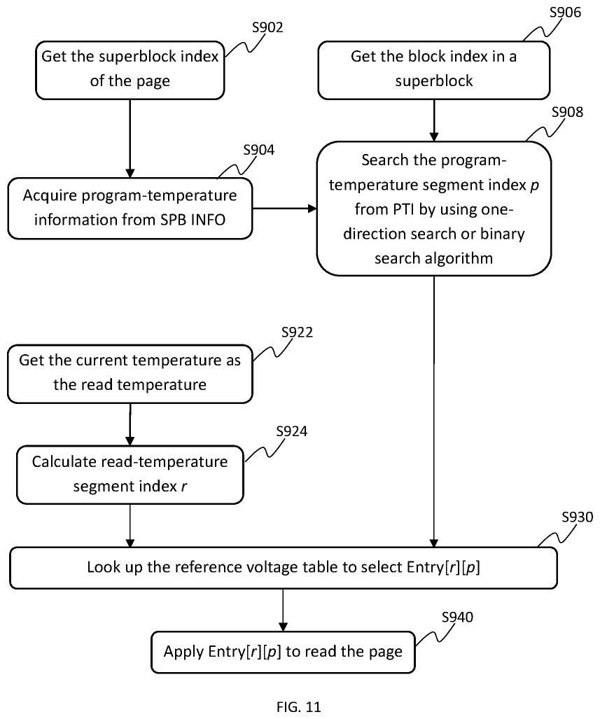

FIG. 11 is a flowchart of a page reading process in accordance with Embodiment Ill of the present disclosure.

When a page is about to be read, in step S902, the superblock index of the superblock containing the page can be acquired, for example, based on the L2P (Logical address to Physics address) table.

In step S904, the SPB INFO associated with the superblock can be acquired, from the storage 108 for example. As described above, the SPB INFO comprises a representation of the programing temperature of the superblock, or PTI.

In step S906, the block index of the page in a superblock is obtained, and further, the block group index can be calculated, which may provide the index for the PTI.

In step S908, the programing temperature segment index p of the block group containing the page to be read can be acquired from the PTI, or the representation of the PTI, stored in a record in the storage 108, as a part of SPB INFO.

In step S908, the programing temperature segment index (p) can be calculated by the one-direction search algorithm or binary search algorithm.

Below is a brief flowchart of the one-direction search algorithm.

```
For i = (n−1):0
  if B >= PTI[i][0]
    p = PTI[i][1]
    break
```

Wherein, n is the number of entries of the PTI of the superblock stored in the record in the storage, B is the block group index of a page to be read.

On the other hand, when the page is about to be read, in step S922, the current read temperature can be acquired by using the temperature sensor 110.

And then, in step S924, the read temperature segment index r can be calculated accordingly.

With the read temperature segment index r and the programing temperature segment index p available, in step S930, Entry[r][p] can be selected by looking up the reference voltage table.

And then, in step S940, the reference voltage in Entry[r][p] can be applied to read the page.

As described above with reference to FIG. 5, an error recovery process may be performed. Assuming Entry[r][p] is the selection, if the selected entry is not good to recovery the page data, entries in the same row of the look-up table will be tried one by one ordered in increasing value based on the absolute value of the difference between the programing temperature segment indexes of the selected entry and those of the successive entries. If all entries in the r-th row are unsuccessful, another error recovery method such as soft read could be used.

Below, two examples of read reverence voltage selection of Embodiment are described with references to FIGS. 9 and 10.

In the example shown in FIG. 9, if block index of the page to be read is 9, then the block group index is 9.

The current temperature is 10° C. The read temperature segment index r is 0, i.e., r=0.

By using either one-direction search algorithm or binary search algorithm, it can be determined that the programing temperature segment index p is 3, i.e., p=3.

Therefore, the reference voltage in Entry[0][3] is used to read the page.

According to the error recovery process described before with reference to FIG. 5, if the reference voltage in Entry[0][3] is unsuccessful, i.e., the read operation fails, another entry in the first row will be used in the order of Entry[0][2], Entry[0][1], and Entry[0][0].

If all the four entries in the first row of Table 1 are unsuccessful, soft read can be used to read the page.

In the example shown in FIG. 10, if the block group index of the page to be read: 9, then the block group index is 4.

The current temperature is 10° C. The read temperature segment index r is 0, i.e., r=0.

By using either one-direction search algorithm or binary search algorithm, it can be determined that the programing temperature segment index p is 3, i.e., p=3.

Therefore, the reference voltage in Entry[0][3] is used to read the page.

According to the error recovery process described before with reference to FIG. 5, if the reference voltage in Entry[0][3] is unsuccessful, i.e., the read operation fails, another entry in the first row will be used in the order of Entry[0][2], Entry[0][1], and Entry[0][0].

If all the four entries in the first row of Table 1 are unsuccessful, soft read can be used to read the page.

In an embodiment, a system includes the controller as described in this disclosure. The system may be a solid-state drive (SSD), a flash drive, a mother board, a processor, a computer, a server, a gaming device, or a mobile device.

In an embodiment, a non-transitory machine-readable medium having information stored thereon. The information, when read by a hardware processor system, causes the hardware processor system to perform any of the disclosed method.

Any of the disclosed methods and operations may be implemented as computer-executable instructions (e.g., software code for the operations described herein) stored on one or more computer-readable storage media (e.g., non-transitory computer-readable media, such as one or more optical media discs, volatile memory components (such as DRAM or SRAM), or nonvolatile memory components (such as hard drives)) and executed on a device controller (e.g., firmware executed by ASIC). Any of the computer-executable instructions for implementing the disclosed techniques as well as any data created and used during implementation of the disclosed embodiments can be stored on one or more computer-readable media (e.g., non-transitory computer-readable media).

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A controller, comprising:
a processor configured to obtain a record from a storage;
wherein the record comprises a representation of a programing temperature of a superblock of non-volatile memories;
wherein the non-volatile memories are on a plurality of dies;
wherein the superblock comprises blocks of the non-volatile memories and the blocks are not on the same die;
wherein the processor is further configured to determine a reference voltage based on the representation of the programing temperature and to read a page of the superblock using the reference voltage.

2. The controller of claim 1, wherein the representation of the programing temperature is the programing temperature.

3. The controller of claim 1, wherein the representation of the programing temperature is a temperature segment index representing a range the programing temperature is in.

4. The controller of claim 1, wherein the superblock is divided into a plurality of block groups; wherein the record further comprises an index of a block group among the plurality of block groups.

5. The controller of claim 4, wherein the processor is configured to determine the reference voltage further based on the index of the block group.

6. The controller of claim 1, wherein the superblock is divided into a plurality of block groups; wherein the representation of the programing temperature comprises a first representation of a first programing temperature of a first block group among the plurality of block groups and a second representation of a second programing temperature of a second block group among the plurality of block groups.

7. The controller of claim 6, wherein the first programing temperature is at a beginning or an end of programming the first block group.

8. The controller of claim 6, wherein the processor is configured to determine the reference voltage based on the first representation of the first programing temperature and the second representation of the second programing temperature.

9. The controller of claim 8, wherein the processor is configured to determine the reference voltage by interpolation or extrapolation, using the first representation of the first programing temperature and the second representation of the second programing temperature.

10. The controller of claim 1, wherein the controller is configured to read the page of the superblock using the reference voltage with an offset.

11. The controller of claim 1, wherein the processor is configured to determine the reference voltage further based on a representation of a temperature of the non-volatile memories at a time of determining the reference voltage.

12. The controller of claim 1, wherein the processor is configured to determine the reference voltage further based on an index of the superblock.

13. The controller of claim 1, wherein the processor is configured to determine the representation of the programing temperature based on a temperature at programing the superblock and to store the representation of the programing temperature into the record.

14. The controller of claim 1, wherein the storage is in the controller or in the non-volatile memories.

15. A system, comprising the controller of claim 1, wherein the system is a solid-state drive (SSD), a flash drive, a mother board, a processor, a computer, a server, a gaming device, or a mobile device.

16. A method comprising:
obtaining a record from a storage, wherein the record comprises a representation of a programing temperature of a superblock of non-volatile memories; wherein the non-volatile memories are on a plurality of dies; wherein the superblock comprises blocks of the non-volatile memories and the blocks are not on the same die;
determining a reference voltage based on the representation of the programing temperature; and
reading a page of the superblock using the reference voltage.

17. The method of claim 16, wherein the representation of the programing temperature is the programing temperature.

18. The method of claim 16, wherein the representation of the programing temperature is a temperature segment index representing a range the programing temperature is in.

19. The method of claim 16, wherein the superblock is divided into a plurality of block groups; wherein the record further comprises an index of a block group among the plurality of block groups.

20. The method of claim 19, wherein determining the reference voltage is further based on the index of the block group.

21. The method of claim 16, wherein the superblock is divided into a plurality of block groups; wherein the representation of the programing temperature comprises a first representation of a first programing temperature of a first block group among the plurality of block groups and a second representation of a second programing temperature of a second block group among the plurality of block groups.

22. The method of claim 21, wherein the first programing temperature is at a beginning or an end of programming the first block group.

23. The method of claim 21, wherein determining the reference voltage is based on the first representation of the first programing temperature and the second representation of the second programing temperature.

24. The method of claim 23, wherein determining the reference voltage is by interpolation or extrapolation, using the first representation of the first programing temperature and the second representation of the second programing temperature.

25. The method of claim 16, further comprising reading the page using the reference voltage with an offset.

26. The method of claim 16, wherein determining the reference voltage is further based on a representation of a temperature at a time of determining the reference voltage.

27. The method of claim 16, wherein determining the reference voltage is further based on an index of the superblock.

28. The method of claim 16, wherein the storage is in a controller or in the non-volatile memories.

29. A non-transitory machine-readable medium having information, wherein the information, when read by a hardware processor system, causes the hardware processor system to perform the method of claim 16.
